(19) United States
(12) Patent Application Publication
(10) Pub. No.: US 2024/0162047 A1
(43) Pub. Date: May 16, 2024

(54) ETCHING METHOD, METHOD FOR MANUFACTURING SEMICONDUCTOR DEVICE, ETCHING PROGRAM, AND PLASMA PROCESSING APPARATUS

(71) Applicant: Tokyo Electron Limited, Tokyo (JP)

(72) Inventors: Takahiro YOKOYAMA, Miyagi (JP); Masafumi URAKAWA, Boise, ID (US); Yuki CHIBA, Miyagi (JP)

(73) Assignee: Tokyo Electron Limited, Tokyo (JP)

(21) Appl. No.: 18/422,013

(22) Filed: Jan. 25, 2024

Related U.S. Application Data
(63) Continuation of application No. PCT/JP2022/025435, filed on Jun. 27, 2022.

(30) Foreign Application Priority Data
Jul. 27, 2021 (JP) 2021-122118
Feb. 7, 2022 (JP) 2022-016830
Feb. 11, 2022 (TW) 111105078

(51) Int. Cl. H01L 21/311; H01J 37/32; H01L 21/033

(52) U.S. Cl. CPC H01L 21/31144; H01J 37/32091; H01J 37/32449; H01J 37/32926; H01L 21/0332; H01L 21/0337; H01L 21/31116; H01J 2237/3346

(57) ABSTRACT

An etching method includes providing a substrate including an etching target layer including a silicon-containing layer, and a mask located on the etching target layer, comprising a metal, and having an opening defined by a side wall of the mask, supplying a process gas including a metal-containing gas, and etching, with plasma generated from the process gas, the etching target layer through the opening while forming a protective layer comprising a metal on a top of the mask and on the side wall of the mask.

### CROSS-REFERENCE TO RELATED APPLICATIONS

This application is a continuation application of International Patent Application No. PCT/JP2022/025435, filed on Jun. 27, 2022, which claims priority from Japanese Patent Application Nos. 2021-122118, filed on Jul. 27, 2021, 2022-016830, filed on Feb. 27, 2022, and Tawain Patent Application No. 111105078, filed on Feb. 11, 2022, all of each are incorporated herein in their entireties by reference.

### FIELD

The present disclosure relates to an etching method, a method for manufacturing a semiconductor device, an etching program, and a plasma processing apparatus.

### BACKGROUND

In etching an insulating film such as an oxide film with plasma such as a gas containing carbon and fluorine, a WF₆ gas may be added to the etching gas to form a conductive layer and reduce feature failures resulting from local charging.

### CITATION LIST

### Patent Literature

Patent Literature 1: Japanese Unexamined Patent Application Publication No. 9-50984

### BRIEF SUMMARY

### Technical Problem

One or more aspects of the present disclosure are directed to an etching method, a method for manufacturing a semiconductor device, an etching program, and a plasma processing apparatus that can improve selectivity to a metal-containing mask.

### Solution to Problem

An etching method according to one aspect of the present disclosure includes providing a substrate including an etching target layer including a silicon-containing layer, and a mask located on the etching target layer, comprising a metal, and having an opening defined by a side wall of the mask, supplying a process gas including a metal-containing gas, and etching, with plasma generated from the process gas, the etching target layer through the opening while forming a protective layer comprising a metal on a top of the mask and on the side wall of the mask.

### Advantageous Effects

The technique according to the above aspect of the present disclosure improves selectivity to a metal-containing mask.

### BRIEF DESCRIPTION OF DRAWINGS

FIG. 1 is a schematic cross-sectional view of an example plasma processing apparatus according to an embodiment of the present disclosure.

FIG. 2 is a schematic diagram of a substrate to be etched by the plasma processing apparatus according to the embodiment, showing its example structure.

FIG. 3 is a schematic diagram describing an example procedure of etching the substrate in the embodiment.

FIG. 4 is a flowchart of example etching in the embodiment.

FIG. 5 is a table showing example experimental results in the embodiment and a comparative example.

FIG. 6 is a graph showing example relationships between a flow rate of a tungsten hexafluoride gas and a selectivity to a mask.

FIG. 7 is a graph showing example relationships between a bias voltage and a selectivity to the mask.

### DETAILED DESCRIPTION

An etching method, a method for manufacturing a semiconductor device, an etching program, and a plasma processing apparatus according to an embodiment of the present disclosure will now be described in detail with reference to the drawings. The technique according to the present disclosure is not limited to the embodiment described below. In etching a dielectric film using, for example, a mask containing a metal, or a metal-containing mask, such as tungsten carbide (WC), the metal-containing mask may be etched, decreasing the selectivity (the etch rate of the dielectric film to the etch rate of the metal-containing mask). The decreased selectivity to the metal-containing mask can be an issue in semiconductor processes that have been increasingly finer. The selectivity to the metal-containing mask is thus to be improved.

### Structure of Plasma Processing Apparatus 10

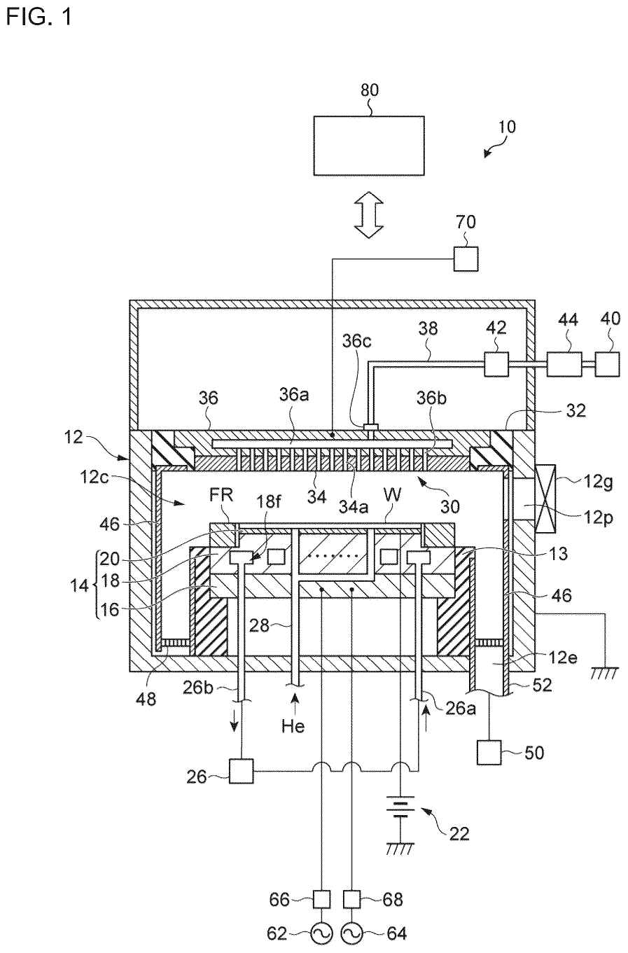

FIG. 1 is a schematic cross-sectional view of an example plasma processing apparatus according to an embodiment of the present disclosure. A plasma processing apparatus 10 shown in FIG. 1 is a capacitively coupled plasma processing apparatus. The plasma processing apparatus 10 includes a chamber 12. The chamber 12 is substantially cylindrical. The chamber 12 has an internal space serving as a processing space 12c. The chamber 12 is formed from, for example, aluminum. The chamber 12 has its inner wall surfaces processed to be plasma resistant. For example, the chamber 12 has its inner wall surfaces processed with anodic oxidation. The chamber 12 is electrically grounded.

The chamber 12 has a side wall having a port 12p. A wafer (substrate) W as an example processing target is loaded into and unloaded from the processing space 12c through the port 12p. This port 12p can be open and closed with a gate valve 12g.

A support 13 is located on the bottom of the chamber 12. The support 13 is formed from an insulating material. The support 13 is substantially cylindrical. The support 13 extends vertically from the bottom of the chamber 12 in the processing space 12c. The support 13 supports a stage 14. The stage 14 is located in the processing space 12c. The stage 14 is an example of a mount table and a substrate support.

The stage 14 includes a lower electrode 18 and an electrostatic chuck (ESC) 20. The stage 14 may further include an electrode plate 16. The electrode plate 16 is substantially disk-shaped and is formed from a conductor such as aluminum. The lower electrode 18 is located on the electrode plate 16. The lower electrode 18 is substantially disk-shaped and is formed from a conductor such as aluminum. The lower electrode 18 is electrically coupled to the electrode plate 16.

The ESC 20 is located on the lower electrode 18. The wafer W is placed on the upper surface of the ESC 20. The ESC 20 includes a body formed from a dielectric. The body in the ESC 20 includes a film electrode. The electrode in the ESC 20 is coupled to a direct current (DC) power supply 22 with a switch. A voltage is applied from the DC power supply 22 to the electrode in the ESC 20 to generate an electrostatic attraction between the ESC and the wafer W. The electrostatic attraction causes the ESC 20 to attract and hold the wafer W.

A focus ring FR is placed on the periphery of the lower electrode 18 to surround the edge of the wafer W. The focus ring FR is an example of an edge ring to facilitate uniform etching. The focus ring FR may be formed from, but not limited to, silicon, silicon carbide, or quartz.

The lower electrode 18 has an internal channel 18f. A heat-exchange medium (e.g., refrigerant) is supplied to the internal channel 18f from a chiller unit 26 external to the chamber 12 through a pipe 26a. The heat-exchange medium supplied to the internal channel 18f returns to the chiller unit 26 through a pipe 26b. In the plasma processing apparatus 10, the temperature of the wafer W on the ESC 20 is adjusted through heat exchange between the heat-exchange medium and the lower electrode 18.

The plasma processing apparatus 10 includes a gas supply line 28. The gas supply line 28 supplies a heat transfer gas (e.g., He gas) from a heat transfer gas supply assembly between the upper surface of the ESC 20 and the back surface of the wafer W. The plasma processing apparatus 10 further includes an upper electrode 30. The upper electrode 30 is located above the stage 14. The upper electrode 30 is supported on an upper portion of the chamber 12 with a member 32. The member 32 is formed from an insulating material. The upper electrode 30 may include a ceiling plate 34 and a support member 36. The ceiling plate 34 has its lower surface exposed to and defining the processing space 12c. The ceiling plate 34 may be formed from a low resistance conductor or a semiconductor with less Joule heat. The ceiling plate 34 has multiple gas outlet holes 34a. The gas outlet holes 34a are through-holes in the thickness direction of the ceiling plate 34.

The support member 36 supports the ceiling plate 34 in a detachable manner and may be formed from a conductive material such as aluminum. The support member 36 has an internal gas-diffusion compartment 36a. Multiple gas inlet holes 36b connecting with the respective gas outlet holes 34a extend downward from the gas-diffusion compartment 36a. The support member 36 has a gas inlet 36c to guide a process gas into the gas-diffusion compartment 36a. The gas inlet 36c is connected to a gas supply pipe 38. The gas inlet 36c is an example of a gas supply port to supply a gas into the chamber 12.

The gas supply pipe 38 is connected to a set of gas sources 40 through a set of valves 42 and a set of flow controllers 44. The gas source set 40 includes multiple gas sources. The gas sources include multiple sources of gases included in the process gas used for, for example, etching. The valve set 42 includes multiple open-close valves. The flow controller set 44 includes multiple flow controllers. Each flow controller is a mass flow controller or a pressure-based flow controller. The gas sources in the gas source set 40 are connected to the gas supply pipe 38 through the respective valves in the valve set 42 and through the respective flow controllers in the flow controller set 44.

The plasma processing apparatus 10 includes a shield 46 along the inner wall of the chamber 12 in a detachable manner. The shield 46 also extends along the outer periphery of the support 13. The shield 46 prevents an etching product from accumulating on the chamber 12. The shield 46 may be formed from, for example, an aluminum material coated with ceramic such as Y₂O₃.

A baffle plate 48 is located between the support 13 and the side wall of the chamber 12. The baffle plate 48 includes, for example, an aluminum base coated with ceramic such as Y₂O₃. The baffle plate 48 has multiple through-holes. The chamber 12 has an outlet 12e in its bottom below the baffle plate 48. The outlet 12e is connected to an exhaust device 50 through an exhaust pipe 52. The exhaust device 50 includes a pressure control valve and a vacuum pump such as a turbomolecular pump.

The plasma processing apparatus 10 further includes a first radio-frequency (RF) power supply 62 and a second RF power supply 64. The first RF power supply 62 generates a first RF for plasma generation. The first RF is within, for example, a range of 27 to 100 MHz. The first RF power supply 62 is coupled to the lower electrode 18 with an impedance matching circuit, or a matcher 66, and the electrode plate 16 in between. The matcher 66 includes a circuit for matching the output impedance of the first RF power supply 62 and the input impedance of a load (the lower electrode 18). The first RF power supply 62 may be coupled to the upper electrode 30 with the matcher 66 in between. The first RF power supply 62 is an example of a plasma generator.

The second RF power supply 64 generates a second RF for drawing ions to the wafer W. The second RF is lower than the first RF. The second RF is within, for example, a range of 400 kHz to 13.56 MHz. The second RF power supply 64 is coupled to the lower electrode 18 with an impedance matching circuit, or matcher 68, and the electrode plate 16 in between. The matcher 68 includes a circuit for matching the output impedance of the second RF power supply 64 and the input impedance of a load (the lower electrode 18).

The plasma processing apparatus 10 may further include a DC power supply 70. The DC power supply 70 is coupled to the upper electrode 30. The DC power supply 70 generates and applies a negative DC voltage to the upper electrode 30.

The plasma processing apparatus 10 may further include a controller 80. The controller 80 may be a computer including a processor, a storage, an input device, and a display. The controller 80 controls the components of the plasma processing apparatus 10. An operator can use the input device in the controller 80 to input a command or perform other operations for managing the plasma processing apparatus 10. The display in the controller 80 can display and visualize the operating state of the plasma processing apparatus 10. The storage in the controller 80 stores a control program for controlling, with the processor, processing performed in the plasma processing apparatus 10, and recipe data. The processor in the controller 80 executes the control program to control the components of the plasma processing apparatus 10 in accordance with the recipe data, allowing the plasma processing apparatus 10 to perform intended processing.

For example, the controller 80 controls the components of the plasma processing apparatus 10 to implement an etching method described later. In an example, more specifically, the controller 80 performs an operation of providing a wafer (substrate) W including an etching target layer including a silicon-containing layer, and a mask located on the etching target layer. The mask contains a metal and has openings defined by its side walls. The controller 80 also performs an operation of supplying a process gas including a metal-containing gas. The controller 80 then performs an operation of etching, with plasma generated from the process gas, the etching target layer through the openings while forming a protective layer containing a metal on the top and the side walls of the mask.

### Target Substrate

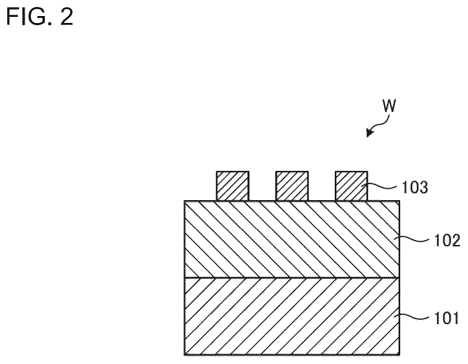

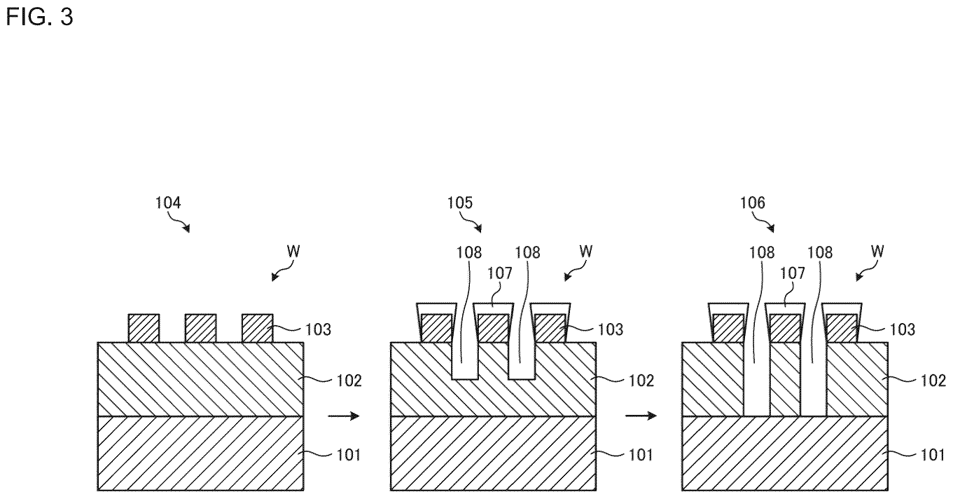

A substrate as an etching target will now be described with reference to FIGS. 2 and 3. FIG. 2 is a schematic diagram of the substrate to be etched by the plasma processing apparatus according to the present embodiment, showing its example structure. The wafer W shown in FIG. 2 includes a silicon-containing layer 102 and a mask 103 on a silicon substrate 101. Examples of the silicon-containing layer (film) 102 include a silicon oxide (SiO₂) layer, a silicon nitride (SiN) layer, and a low-k layer. The silicon-containing layer 102 is an example of a silicon-containing dielectric layer. The low-k layer may be, for example, a SiOC layer. The silicon-containing layer 102 may be a stack of a SiO₂ layer and a low-k layer, a SiO₂ layer and a SiN layer, or a SiN layer and a low-k layer. The silicon-containing layer 102 is an example of the etching target layer.

The mask 103 is a mask pattern layer having openings in a predetermined pattern such as a comb-shaped pattern defined by its side walls. The mask 103 is, for example, a metal-containing mask. Examples of the metal-containing mask include a tungsten mask, a WC mask, a molybdenum mask, and a titanium nitride (TiN) mask. The pitch between the openings in the mask 103 is, for example, about 30 nm. The line critical dimension (CD) is, for example, about 10 nm. The mask 103 has a thickness of, for example, about 20 nm. The silicon-containing layer 102 has a thickness of, for example, about 200 nm. In the present embodiment, the wafer W as an etching target is a substrate for a logic device. The wafer W as an etching target may be used for devices other than a logic device and may be, for example, a substrate for a memory with a high aspect ratio of 30 or more.

Examples of a metal or a metal compound contained in the mask 103 include, in addition to the examples described above, tungsten (W), WC_{α}, where α is a real number greater than 0 (e.g., α=1), tungsten silicide (WSi_{β}), where β is a real number greater than 0 (e.g., β=1 or 2), titanium (Ti), TiN_{γ}, where γ is a real number greater than 0 (e.g., γ=1), tantalum nitride (TaN_{δ}), where δ is a real number greater than 0 (e.g., δ=1), molybdenum carbide (Mo_{ε}C), where c is a real number greater than 0 (e.g., ε=1 or 2), molybdenum nitride (MoSi_{ζ}), where ζ is a real number greater than 0 (e.g., ζ=1 or 2), molybdenum silicide (MoSi_{η}), where η is a real number greater than 0 (e.g., η=1 or 2), molybdenum boride (MoB_{Θ}), where Θ is a real number greater than 0 (e.g., Θ=1, 2, or 3), molybdenum oxide (MoO_{ι}), where t is a real number greater than 0 (e.g., ι=1, 2, or 3), rhenium (Re), rhenium oxide (ReO_{κ}), where κ is a real number greater than 0 (e.g., κ=1, 2, or 3), and rhenium nitride (ReN_{λ}), where λ is a real number greater than 0 (e.g., λ=1 or 2). The mask 103 may contain a metallic element such as W, Ti, tantalum (Ta), molybdenum (Mo), or Re. The mask 103 may also contain boron nitride (BN). The mask 103 may contain a nonmetallic element such as boron (B), carbon (C), nitrogen (N), oxygen (O), silicon (Si), phosphorus (P), or sulfur (S).

FIG. 3 is a schematic diagram describing an example procedure of etching the substrate in the present embodiment. In the present embodiment, the silicon-containing layer 102 on the wafer W is etched as shown in the states 104 to 106 in FIG. 3. The state 104 shows the silicon-containing layer 102 before etching. The state 105 shows the silicon-containing layer 102 being etched, with a protective layer 107 containing tungsten being formed on the top (upper surface) and the side walls of the mask 103 and with grooves 108 being formed through the openings in the mask 103. The protective layer 107 is thin on the side walls of the mask 103 and thick on the upper portions of the mask 103. In other words, the protective layer 107 has a greater thickness on the top of the mask 103 than on the side walls of the mask 103. For example, the protective layer 107 may have a thickness of about 1 nm on the side walls of the mask 103, and the thickness ratio of the film on the top to the film on the side walls (the film thickness on the top to the film thickness on the side walls) may be greater than or equal to 2 and less than 5. In some embodiments, the thickness ratio of the film on the top to the film on the side walls (the film thickness on the top to the film thickness on the side walls) may be greater than or equal to 5. In some embodiments, the thickness ratio of the film on the top to the film on the side walls (the film thickness on the top to the film thickness on the side walls) may be less than 2. The protective layer 107 may have, on the side walls of the mask 103, a thickness decreasing in the depth direction from upper portions adjacent to the openings. In some etching processes, the protective layer 107 may have a smaller or the same thickness on the top of the mask 103 than on the side walls of the mask 103. The state 106 shows the silicon-containing layer 102 etched further than in the state 105, with the grooves 108 reaching the silicon substrate 101. When the etching is performed to reach the state 106, a predetermined feature (a predetermined aspect ratio in an example) is determined to have been obtained, and etching ends. In FIG. 3, the etching states of portions other than two grooves 108 are not shown.

### Etching Method

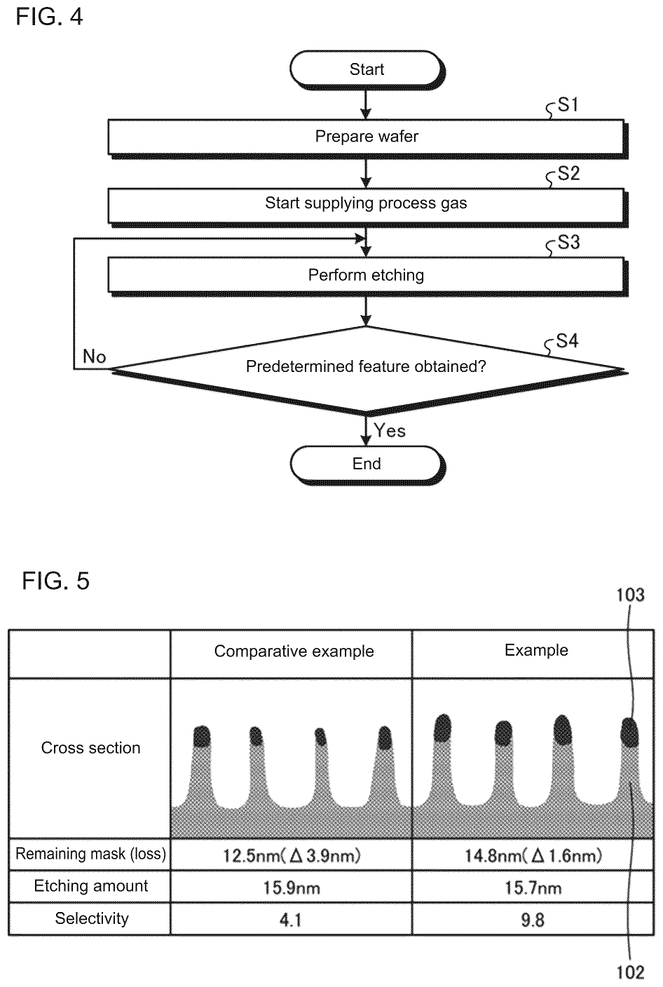

An etching method according to the present embodiment will now be described. FIG. 4 is a flowchart of example etching in the present embodiment.

In the etching method according to the present embodiment, the controller 80 controls the gate valve 12g to be open. The wafer W including the mask 103 on the silicon-containing layer 102 is loaded into the chamber 12 and placed onto the ESC 20 in the stage 14. The wafer W is held on the ESC 20 with a DC voltage applied to a clamping electrode (not shown) in the ESC 20. The controller 80 then controls the gate valve 12g to be closed and controls the exhaust device 50 to evacuate the processing space 12c, causing the processing space 12c to have an atmosphere with a predetermined degree of vacuum. The controller 80 also controls a temperature control module (not shown) to adjust the temperature of the wafer W to a predetermined temperature (step S1).

The controller 80 then controls supply of the process gas to start (step S2). The controller 80 controls a mixture gas of WF₆, C₄F₆, O₂, and Ar as the process gas including a tungsten-containing gas (hereafter referred to as a WF₆/C₄F₆/O₂/Ar gas) to be supplied into the gas inlet 36c. The gas containing carbon and fluorine, such as C₄F₆, may include one or more of a fluorocarbon gas and a hydrofluorocarbon gas. In other words, the gas containing carbon and fluorine contains CₓH_{y}F_{z}, where x and z are each an integer greater than or equal to 1 and y is an integer greater than or equal to 0. CₓH_{y}F_{z} is a compound with a carbon-fluorine bond, such as C₂F₄, CF₄, C₃F₄, C₃F₈, C₄F₈, C₄F₆, C₅F₈, CH₂F₂, CH₂F₃, CHF₃, or CH₃F. The oxygen-containing gas may be a CO gas or a CO₂ gas. The process gas may not include the oxygen-containing gas such as O₂. The Ar gas may be another noble gas such as a Xe gas, or an inert gas such as a N₂ gas in place of a noble gas.

The process gas may not include a tungsten-containing gas and may include another metal-containing gas. Examples of the metal-containing gas include, for example, a tungsten hexabromide (WBr₆) gas, a tungsten hexachloride (WCl₆) gas, a WF₅Cl gas, a tungsten hexacarbonyl (W(CO)₆) gas, a titanium tetrachloride (TiCl₄) gas, a molybdenum pentafluoride (MoF₅) gas, a vanadium hexafluoride (VF₆) gas, a platinum hexafluoride (PtF₆) gas, a hafnium tetrafluoride (HfF₄) gas, and a niobium pentafluoride (NbF₅) gas, in addition to the WF₆ gas described above. The metal-containing gas may be a metal halogen-containing gas. The metal-containing gas may further contain a metallic element such as W, Ti, Mo, vanadium (V), Pt, hafnium (Hf), niobium (Nb), Ta, or Re.

The process gas supplied into the gas inlet 36c is then supplied into the gas-diffusion compartment 36a to diffuse. The process gas diffused in the gas-diffusion compartment 36a is supplied into the processing space 12c in the chamber 12 through the multiple gas outlet holes 34a in a shower-like manner.

The controller 80 controls the first RF power supply 62 to provide RF power (first RF power) for plasma generation to the lower electrode 18. In other words, in the processing space 12c, plasma is generated from the process gas using RF power for plasma generation. RF power for plasma generation may be less than 5 kW and less than or equal to 5.6 W/cm². The wafer W is processed with the generated plasma. In other words, the controller 80 controls RF power for plasma generation to be provided into the chamber 12 to generate plasma from the process gas, and to perform etching on the silicon-containing layer 102 through the mask 103 (step S3). Although no electrical bias voltage (second RF power) is provided from the second RF power supply 64 in the present embodiment, ions in plasma are drawn to the wafer W with RF power for plasma generation provided to the lower electrode 18, allowing etching.

The controller 80 determines whether the predetermined feature is obtained in step S3 based on, for example, information obtained from a sensor (not shown) in the plasma processing apparatus 10 or the processing time in accordance with the recipe (step S4). When determining that the predetermined feature is not obtained (No in step S4), the controller 80 returns the process to step S3. When determining that the predetermined feature is obtained (Yes in step S4), the controller 80 ends the process.

To end the process, the controller 80 controls supply of the process gas to stop. The controller 80 also controls a DC voltage with the opposite polarity to be applied to the ESC 20 and eliminate static electricity, causing the wafer W to separate from the ESC 20. The controller 80 controls the gate valve 12g to be open. The wafer W is unloaded from the processing space 12c in the chamber 12 through the port 12p.

The unloaded wafer W is processed with, for example, another substrate processing apparatus to remove the mask 103 and form a conductive material that serves as a contact pad. In other words, a semiconductor device including the wafer W processed with the etching method described above is manufactured.

Experimental Results

Experimental results will now be described with reference to FIGS. 5 to 7. FIG. 5 is a table showing example experimental results in the present embodiment and a comparative example. FIG. 5 shows experimental results in the comparative example in which the process gas containing no WF₆ and in an example corresponding to the present embodiment in which the process gas containing WF₆. The processing conditions were as described below. The silicon-containing layer 102 in the wafer W is a SiO₂ layer. The mask 103 is formed from WC.

### Processing Conditions

First RF power (40 MHz): 300 W
Second RF power (400 kHz): 0 W
Process gas in the comparative example: C₄F₆/O₂/Ar gas
Process gas in the example: WF₆/C₄F₆/O₂/Ar gas
(with the flow ratio of WF₆ being 1% or less)
Processing time: 30 seconds

As shown in FIG. 5, the remaining amount of the mask 103 is 12.5 nm in the comparative example, whereas 14.8 nm in the example. The loss (the amount of wear) of the mask 103 is 3.9 nm in the comparative example, whereas the loss is decreased to 1.6 nm in the example. The etching amount in each example was adjusted to obtain substantially the same depth. The etching depth is 15.9 nm in the comparative example and 15.7 nm in the example. The selectivity to the mask is 4.1 in the comparative example, whereas the selectivity to the mask is improved to 9.8 in the example, which is more than twice the selectivity of the comparative example.

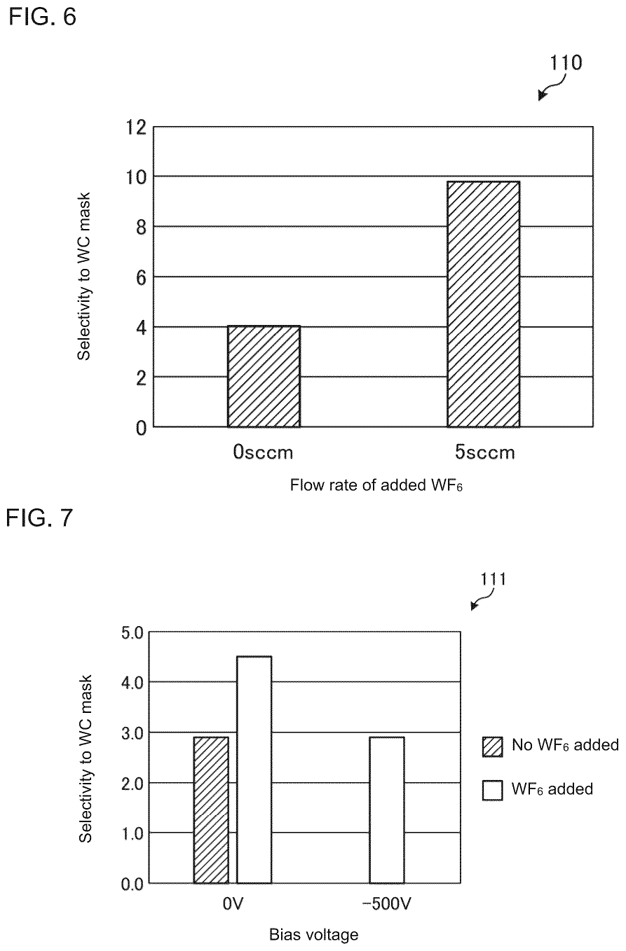

FIG. 6 is a graph showing example relationships between the flow rate of the tungsten hexafluoride gas and the selectivity to the mask. The graph 110 in FIG. 6 shows the relationships between the flow rate of the WF₆ gas and the selectivity to the mask in the experiment results in FIG. 5. As shown in the graph 110, in the comparative example in which the flow rate of the added WF₆ gas is 0 sccm, the selectivity to the WC mask is 4.1. In the example in which the flow rate of the added WF₆ gas is 5 sccm, the selectivity to the WC mask is 9.8. In other words, the selectivity to the WC mask 103 as a metal-containing mask to the silicon-containing layer 102 as a silicon oxide layer can be improved (increased) by adding the WF₆ gas to the process gas. The flow rate (flow rate proportion) of the WF₆ gas to the entire process gas may be 10% or less, or more specifically, 5% or less, or still more specifically, 1% or less.

The effect of the electrical bias voltage on the selectivity to the mask will now be described. FIG. 7 is a graph showing example relationships between the bias voltage and the selectivity to the mask. A graph 111 in FIG. 7 shows the selectivity to the WC mask when, with the WF₆ gas added to the process gas, no electrical bias voltage (referred to as bias voltage in FIG. 7) is provided (0 V) and when the bias voltage is provided (−500 V). The graph 111 also shows, as a reference, the selectivity to the WC mask when no electrical bias voltage is provided (0 V) with no WF₆ gas added to the process gas. As shown in the graph 111, the selectivity to the WC mask is improved by adding the WF₆ gas when no bias voltage is provided (0 W). In contrast, the selectivity to the WC mask is unimproved by adding the WF₆ gas when the bias voltage is provided (−500 V). In other words, a smaller bias voltage improves the selectivity to the WC mask more.

To increase the etching rate in etching, for example, an electrical bias voltage for drawing ions may be provided from the second RF power supply 64 to the lower electrode 18. In this case, the electrical bias may have a voltage of −500 to 0 V inclusive.

As in the above embodiment, a predetermined amount of WF₆ added to the process gas with no or a low bias voltage provided improves the selectivity to the mask. WF₆ having a high affinity with metallic elements is more likely to be deposited on the metal-containing mask than on the etching target layer being a silicon-containing layer (e.g., a silicon oxide layer, a silicon nitride layer, or a low-k layer). When no or a low bias voltage is provided, ion energy entering the substrate is 0 or low, reducing etching of the deposit. The interaction between adding WF₆ and controlling the bias voltage causes WF₆ to be deposited further on the metal-containing mask, improving the selectivity to the mask. Although the mask containing the same tungsten as the tungsten contained in WF₆ can further improve the bond between the metallic elements, different metals can also produce the same effect. In some embodiments, the etching target layer may be etched with a process gas including a tungsten-containing gas as an additive gas through a mask containing a metal other than tungsten, or may be etched with a process gas including a gas containing a metal other than tungsten as an additive gas through a mask containing tungsten. The etching target layer may also be etched with a process gas including a gas containing a metal other than tungsten as an additive gas through a mask containing a metal other than tungsten. In other words, the mask 103 may contain the same metal as or a metal different from the metal contained in the metal-containing gas. The selectivity to the mask can also be improved in these cases.

In the embodiment described above, the plasma processing apparatus 10 is a capacitively coupled plasma processing apparatus that provides RF power for plasma generation and a bias voltage to the lower electrode 18. However, the plasma processing apparatus 10 may be another apparatus. For example, a capacitively coupled plasma processing apparatus that supplies RF power for plasma generation to the upper electrode 30 and a bias voltage to the lower electrode 18 may be used.

In the present embodiment described above, the controller 80 controls the components of the apparatus to provide the substrate (wafer W) including the etching target layer including the silicon-containing layer 102, and the mask 103 located on the etching target layer. The mask 103 contains a metal and has openings defined by its side walls. The controller 80 controls the components of the apparatus to supply the process gas including a metal-containing gas. The controller 80 controls the components of the apparatus to generate plasma from the process gas and etch the etching target layer through the openings while forming the protective layer containing a metal on the top and the side walls of the mask 103. This improves the selectivity to the mask 103 containing a metal.

In the present embodiment, the mask 103 contains at least one metallic element selected from the group consisting of W, Ti, Ta, Mo, and Re. This improves the selectivity to the mask 103 containing a metal.

In the present embodiment, the mask 103 contains at least one nonmetallic element selected from the group consisting of B, C, N, O, Si, P, and S. This improves the selectivity to the mask 103 containing a metal.

In the present embodiment, the mask 103 contains at least one selected from the group consisting of W, WC, Wsi, Ti, TiN, TaN, MoC, MoN, MoSi, MoB, MoO, Re, ReO, and ReN. This improves (increases) the selectivity of the silicon-containing layer 102 to the mask 103 including at least one selected from the group consisting of W, WC, Wsi, Ti, TiN, TaN, MoC, MoN, MoSi, MoB, MoO, Re, ReO, and ReN.

In the present embodiment, the metal-containing gas is a metal halogen-containing gas. This improves the selectivity to the mask 103 containing a metal.

In the present embodiment, the metal-containing gas contains at least one metallic element selected from the group consisting of W, Ti, Mo, V, Pt, Hf, Nb, Ta, and Re. This improves the selectivity to the mask 103 containing a metal.

In the present embodiment, the metal-containing gas includes at least one gas selected from the group consisting of a WF₆ gas, a WBr₆ gas, a WCl₆ gas, a WF₅Cl gas, a W(CO)₆ gas, a TiCl₄ gas, a MoF₅ gas, a VF₆ gas, a PtF₆ gas, a HfF₄ gas, and a NbF₅ gas. This improves the selectivity to the mask 103 containing a metal.

In the present embodiment, the mask 103 contains the same metal as the metal contained in the metal-containing gas. This improves the selectivity to the mask 103 containing a metal.

In the present embodiment, the mask 103 contains a metal different from the metal contained in the metal-containing gas. This improves the selectivity to the mask 103 containing a metal.

In the present embodiment, the process gas includes a CₓH_{y}F_{z} gas, where x and z are each an integer greater than or equal to 1 and y is an integer greater than or equal to 0. This improves the selectivity to the mask 103 containing a metal.

In the present embodiment, the CₓH_{y}F_{z} gas includes at least one gas selected from the group consisting of CF₄, C₃F₈, C₄F₈, C₄F₆, C₅F₈, CH₂F₂, CHF₃, and CH₃F. This improves the selectivity to the mask 103 containing a metal.

In the present embodiment, the process gas further includes an oxygen-containing gas. This improves the selectivity to the mask 103 containing a metal.

In the present embodiment, the controller 80 provides an electrical bias for drawing ions in etching. The electrical bias has a voltage of −500 to 0 V inclusive. This improves the selectivity to the mask 103 containing a metal in a capacitively coupled plasma processing apparatus that provides RF power for plasma generation to the upper electrode 30.

In the present embodiment, no electrical bias for drawing ions is provided in etching. This improves the selectivity to the mask 103 containing a metal.

In the present embodiment, capacitively coupled plasma or inductively coupled plasma is generated. This improves the selectivity to the mask 103 containing a metal.

In the present embodiment, capacitively coupled plasma is generated, and the substrate support (stage 14) supporting the substrate receives RF power for plasma generation. Ions or other substances are thus drawn to the wafer W by RF power for plasma generation provided to the lower electrode 18 in the stage 14, allowing etching.

In the present embodiment, the protective layer has a greater thickness on the top of the mask than on the side walls of the mask. This improves the selectivity to the mask containing a metal.

In the present embodiment, the protective layer may have, on the side walls of the mask, a thickness decreasing in the depth direction from upper portions adjacent to the openings. This improves the selectivity to the mask containing a metal.

In the present embodiment, the substrate is a substrate for a logic device. Etching is thus performed appropriately for the logic device.

In the present embodiment, a method for manufacturing a semiconductor device includes the etching method described above. This allows the manufacturing of a semiconductor device.

In the present embodiment, an etching program causes the plasma processing apparatus to implement the etching method described above. This allows the plasma processing apparatus to implement the etching method described above.

The embodiment disclosed herein is illustrative in all aspects and should not be construed to be restrictive. The components in the above embodiment may be eliminated, substituted, or modified in various forms without departing from the spirit and scope of the appended claims.

Although the plasma processing apparatus 10 performs processing such as etching on the wafer W using capacitively coupled plasma in the above embodiment, the technique described herein is not limited to this. For a device that processes the wafer W with plasma, the plasma source is not limited to capacitively coupled plasma, and may be any plasma source such as inductively coupled plasma, microwave plasma, or magnetron plasma.

Appendixes according to the above embodiment will be further described below.

### Appendix 1

An etching method, comprising:
providing a substrate including an etching target layer including a silicon-containing layer, and a mask located on the etching target layer, the mask comprising a metal and having an opening defined by a side wall of the mask;
supplying a process gas including a metal-containing gas; and
etching, with plasma generated from the process gas, the etching target layer through the opening while forming a protective layer comprising a metal on a top of the mask and on the side wall of the mask.

### Appendix 2

The etching method according to appendix 1, wherein
the mask comprises at least one metallic element selected from the group consisting of tungsten, titanium, tantalum, molybdenum, and rhenium.

### Appendix 3

The etching method according to appendix 1 or appendix 2, wherein
the mask comprises at least one nonmetallic element selected from the group consisting of boron, carbon, nitrogen, oxygen, silicon, phosphorus, and sulfur.

### Appendix 4

The etching method according to any one of appendixes 1 to 3, wherein
the mask comprises at least one selected from the group consisting of tungsten, tungsten carbide, tungsten silicide, titanium, titanium nitride, tantalum nitride, molybdenum carbide, molybdenum nitride, molybdenum silicide, molybdenum boride, molybdenum oxide, rhenium, rhenium oxide, and rhenium nitride.

### Appendix 5

The etching method according to any one of appendixes 1 to 4, wherein
the metal-containing gas is a metal halogen-containing gas.

### Appendix 6

The etching method according to any one of appendixes 1 to 5, wherein
the metal-containing gas comprises at least one metallic element selected from the group consisting of tungsten, titanium, molybdenum, vanadium, platinum, hafnium, niobium, tantalum, and rhenium.

### Appendix 7

The etching method according to any one of appendixes 1 to 5, wherein
the metal-containing gas includes at least one gas selected from the group consisting of a tungsten hexafluoride gas, a tungsten hexabromide gas, a tungsten hexachloride gas, a WF₅Cl gas, a tungsten hexacarbonyl gas, a titanium tetrachloride gas, a molybdenum pentafluoride gas, a vanadium hexafluoride gas, a platinum hexafluoride gas, a hafnium tetrafluoride gas, and a niobium pentafluoride gas.

### Appendix 8

The etching method according to any one of appendixes 1 to 7, wherein
the mask comprises a same metal as the metal-containing gas.

### Appendix 9

The etching method according to any one of appendixes 1 to 7, wherein
the mask comprises a metal different from a metal in the metal-containing gas.

### Appendix 10

The etching method according to any one of appendixes 1 to 9, wherein
the process gas includes a CₓH_{y}F_{z} gas, where x and z are each an integer greater than or equal to 1 and y is an integer greater than or equal to 0.

### Appendix 11

The etching method according to appendix 10, wherein
the CₓH_{y}F_{z} gas includes at least one gas selected from the group consisting of CF₄, C₃F₈, C₄F₆, C₅F₈, CH₂F₂, CHF₃, and CH₃F.

### Appendix 12

The etching method according to any one of appendixes 1 to 11, wherein
the process gas further includes an oxygen-containing gas.

### Appendix 13

The etching method according to any one of appendixes 1 to 12, wherein
the etching includes providing an electrical bias for drawing ions, and the electrical bias has a voltage of −500 to 0 volts inclusive.

### Appendix 14

The etching method according to any one of appendixes 1 to 12, wherein
the etching includes providing no electrical bias for drawing ions.

### Appendix 15

The etching method according to any one of appendixes 1 to 14, wherein
the generated plasma is capacitively coupled plasma or inductively coupled plasma.

### Appendix 16

The etching method according to any one of appendixes 1 to 15, wherein
the generated plasma is capacitively coupled plasma,
the substrate is supported by a substrate support, and
the substrate support receives radio-frequency power for plasma generation. Appendix 17

The etching method according to any one of appendixes 1 to 16, wherein
the protective layer has a greater thickness on the top of the mask than on the side wall of the mask.

### Appendix 18

The etching method according to appendix 17, wherein
the protective layer has, on the side wall of the mask, a thickness decreasing in a depth direction from an upper portion adjacent to the opening.

### Appendix 19

The etching method according to any one of appendixes 1 to 18, wherein
the substrate is a substrate for a logic device.

### Appendix 20

A method for manufacturing a semiconductor device, the method comprising:
the etching method according to any one of appendixes 1 to 19.

### Appendix 21

An etching program for causing a plasma processing apparatus to implement the etching method according to any one of appendixes 1 to 19.

### Appendix 22

A plasma processing apparatus, comprising:
a chamber;
a substrate support in the chamber;
a gas inlet configured to supply a gas into the chamber;
a plasma generator configured to generate plasma in the chamber; and
a controller configured to perform operations including providing a substrate onto the substrate support, the substrate including an etching target layer including a silicon-containing layer, and a mask located on the etching target layer, the mask comprising a metal,
supplying a process gas including a metal-containing gas; and
etching, with plasma generated from the process gas, the etching target layer through the mask while forming a protective layer comprising a metal on a top of the mask and on a side wall of the mask.

### Appendix 23

The plasma processing apparatus according to appendix 22, wherein
the forming the protective layer includes providing an electrical bias for drawing ions, and
the electrical bias has a voltage of −500 to 0 volts inclusive.

### Appendix 24

The plasma processing apparatus according to appendix 22, wherein
the forming the protective layer includes providing no electrical bias for drawing ions.

### Appendix 25

The plasma processing apparatus according to any one of appendixes 22 to 24, wherein
the generated plasma is capacitively coupled plasma or inductively coupled plasma.

### Appendix 26

The plasma processing apparatus according to any one of appendixes 22 to 24, wherein
the generated plasma is capacitively coupled plasma,
the substrate is supported by the substrate support, and
the substrate support receives radio-frequency power for plasma generation.

### Appendix 27

An etching method, comprising:
providing a substrate including an etching target layer including a silicon oxide layer, and a tungsten-containing mask located on the etching target layer;
supplying a process gas including a tungsten-containing gas; and
etching, with plasma generated from the process gas, the etching target layer through the tungsten-containing mask.

### Appendix 28

A plasma processing apparatus, comprising:
a chamber;
a substrate support in the chamber;
a plasma generator configured to generate plasma in the chamber; and
a controller configured to perform operations including
providing a substrate onto the substrate support, the substrate including an etching target layer including a silicon oxide layer, and a tungsten-containing mask located on the etching target layer;
supplying a process gas including a tungsten-containing gas; and
etching, with plasma generated from the process gas, the etching target layer through the tungsten-containing mask.

### REFERENCE SIGNS LIST

10 Plasma processing apparatus
12 Chamber
14 Stage
18 Lower electrode
30 Upper electrode
62 First RF power supply
64 Second RF power supply
80 Controller
101 Silicon substrate
102 Silicon-containing layer
103 Mask
107 Protective layer
W Wafer

1. An etching method, comprising:
providing a substrate including an etching target layer including a silicon-containing layer, and a mask located on the etching target layer, the mask comprising a metal and having an opening defined by a side wall of the mask;
supplying a process gas including a metal-containing gas; and
etching, with plasma generated from the process gas, the etching target layer through the opening while forming a protective layer comprising a metal on a top of the mask and on the side wall of the mask.

2. The etching method according to claim 1, wherein
the mask comprises at least one metallic element selected from the group consisting of tungsten, titanium, tantalum, molybdenum, and rhenium.

3. The etching method according to claim 1, wherein
the mask comprises at least one nonmetallic element selected from the group consisting of boron, carbon, nitrogen, oxygen, silicon, phosphorus, and sulfur.

4. The etching method according to claim 1, wherein
the mask comprises at least one selected from the group consisting of tungsten, tungsten carbide, tungsten silicide, titanium, titanium nitride, tantalum nitride, molybdenum carbide, molybdenum nitride, molybdenum silicide, molybdenum boride, molybdenum oxide, rhenium, rhenium oxide, and rhenium nitride.

5. The etching method according to claim 1, wherein
the metal-containing gas is a metal halogen-containing gas.

6. The etching method according to claim 1, wherein
the metal-containing gas comprises at least one metallic element selected from the group consisting of tungsten, titanium, molybdenum, vanadium, platinum, hafnium, niobium, tantalum, and rhenium.

7. The etching method according to claim 1, wherein
the metal-containing gas includes at least one gas selected from the group consisting of a tungsten hexafluoride gas, a tungsten hexabromide gas, a tungsten hexachloride gas, a WF₅Cl gas, a tungsten hexacarbonyl gas, a titanium tetrachloride gas, a molybdenum pentafluoride gas, a vanadium hexafluoride gas, a platinum hexafluoride gas, a hafnium tetrafluoride gas, and a niobium pentafluoride gas.

8. The etching method according to claim 1, wherein
the mask comprises a same metal as the metal-containing gas.

9. The etching method according to claim 1, wherein
the mask comprises a metal different from a metal in the metal-containing gas.

10. The etching method according to claim 1, wherein
the process gas includes a CₓH_{y}F_{z} gas, where x and z are each an integer greater than or equal to 1, and y is an integer greater than or equal to 0.

11. The etching method according to claim 10, wherein
the CₓH_{y}F_{z} gas includes at least one gas selected from the group consisting of CF₄, C₃F₈, C₄F₆, C₅F₈, CH₂F₂, CHF₃, and CH₃F.

12. The etching method according to claim 1, wherein
the process gas further includes an oxygen-containing gas.

13. The etching method according to claim 1, wherein
the etching includes providing an electrical bias for drawing ions, and
the electrical bias has a voltage of −500 to 0 volts inclusive.

14. The etching method according to claim 1, wherein
the etching includes providing no electrical bias for drawing ions.

15. The etching method according to claim 1, wherein
the generated plasma is capacitively coupled plasma or inductively coupled plasma.

16. The etching method according to claim 1, wherein
the generated plasma is capacitively coupled plasma,
the substrate is supported by a substrate support, and
the substrate support receives radio-frequency power for plasma generation.

17. The etching method according to claim 1, wherein
the protective layer has a greater thickness on the top of the mask than on the side wall of the mask.

18. The etching method according to claim 17, wherein
the protective layer has, on the side wall of the mask, a thickness decreasing in a depth direction from an upper portion adjacent to the opening.

19. The etching method according to claim 1, wherein
the substrate is a substrate for a logic device.

20. A method for manufacturing a semiconductor device, the method comprising:
the etching method according to claim 1.

21. A non-transitory computer readable storage having computer readable instructions stored therein that upon execution by controller circuitry causes a plasma processing apparatus to implement the etching method according to claim 1.

22. A plasma processing apparatus, comprising:
a chamber;
a substrate support in the chamber;
a gas inlet configured to supply a gas into the chamber;
a plasma generator configured to generate plasma in the chamber; and
a controller that includes circuitry configured to
control moving a substrate onto the substrate support, the substrate including an etching target layer including a silicon-containing layer, and a mask located on the etching target layer, the mask comprising a metal,
control supply of a process gas including a metal-containing gas; and
control an etch operation, with plasma generated from the process gas, on the etching target layer through the mask while forming a protective layer comprising a metal on a top of the mask and on a side wall of the mask.

23. The plasma processing apparatus according to claim 22, wherein
during the forming of the protective layer, the circuitry controls application of an electrical bias for drawing ions in an inclusive voltage range of −500 volts through 0 volts.

24. The plasma processing apparatus according to claim 22, wherein
during the forming of the protective layer, the circuitry does not apply an electrical bias for drawing ions.

25. The plasma processing apparatus according to claim 22, wherein
the generated plasma is capacitively coupled plasma or inductively coupled plasma.

26. The plasma processing apparatus according to claim 22, wherein
the generated plasma is capacitively coupled plasma,
the substrate is supported by the substrate support, and
the substrate support receives radio-frequency power for plasma generation.
